(19) United States
(12) Patent Application Publication
(10) Pub. No.: US 2025/0128934 A1
(43) Pub. Date: Apr. 24, 2025

(54) METHOD FOR SENSOR STATE DETECTION, ENVIRONMENTAL SENSOR SYSTEM AND MOBILE CONSUMER DEVICE

(71) Applicant: Robert Bosch GmbH, Stuttgart (DE)

(72) Inventors: Paul Fehling, Tuebingen (DE); Sujaya Jayadevaiah Umesh, Reutlingen (DE)

(21) Appl. No.: 18/904,367

(22) Filed: Oct. 2, 2024

(30) Foreign Application Priority Data
Oct. 11, 2023 (DE) 10 2023 209 974.8

(51) Int. Cl. B81B 3/00

(52) U.S. Cl. CPC B81B 3/0021; B81B 2201/0221; B81B 2201/0285; B81B 2203/0127; B81B 2203/053

(57) ABSTRACT

A method for sensor state detection of an environmental sensor for measuring at least one physical environmental variable of an ambient medium. The method includes providing the environmental sensor including a micromechanical sensor structure that can be deflected depending on the environmental variable, is exposed to the ambient medium and on which at least one interfering deposit entering via the ambient medium can be deposited and further comprising a converter unit for providing a measured variable depending on the deflection of the sensor structure, detecting an existing deposit of this type on the sensor structure by means of an excitation deviating from the environmental variable, wherein the excitation is a mechanical excitation acting externally on the environmental sensor, via which the deposit moves with an excitation movement on the sensor structure. An environmental sensor system and a mobile consumer device are also described.

### FIELD

The present invention relates to a method for sensor state detection. The present invention also relates to an environmental sensor system and to a mobile consumer device.

### BACKGROUND INFORMATION

PCT Patent Application No. WO 2020/023414 A1 describes a sensor apparatus having liquid detection that, in addition to the sensor unit, uses a liquid detection unit adjacent to the sensor unit that detects the presence of a liquid surrounding the liquid detection unit by measuring electrical or thermal properties of the liquid detection unit.

U.S. Patent Application Publication No. US 2019/0383688 A1 describes a pressure sensor that has separate electrodes for detecting water in the region of the sensor unit.

German Patent Application No. DE 10 2020 209 856 A1 describes a sensor system having a micromechanical sensor structure that can be deflected depending on a physical input variable. The sensor structure can still be deflected depending on an excitation signal generated by a driver unit. An existing deposit on the sensor structure is detected by recording a response behavior of the sensor structure to the excitation signal and comparing it with a reference behavior.

### SUMMARY

According to the present invention, a method for sensor state detection is provided. This allows the deposit to be detected more reliably and accurately. The environmental sensor system is less expensive and easier to implement. The environmental sensor system can be operated more reliably and the environmental variable can be measured more accurately and reliably.

The environmental sensor can be a pressure sensor. The pressure sensor can be a capacitive, piezoresistive or piezoelectric pressure sensor. The environmental sensor can be a microelectromechanical environmental sensor, in particular a microelectromechanical pressure sensor. The environmental sensor can be configured for use in a mobile consumer device.

The ambient medium can be a gas or a liquid. The ambient medium can be air or water.

The environmental variable can be an ambient pressure of the ambient medium. The pressure can be air pressure or water pressure, in particular hydrostatic pressure. The environmental variable can be independent of the amount of ambient medium present at the sensor structure.

According to an example embodiment of the present invention, the sensor structure can comprise a sensor membrane. The sensor membrane can be deflected depending on a differential pressure between the upper side and underside of the sensor membrane. The differential pressure can be expressed as a force acting on the surface of the sensor membrane.

The sensor structure can be a microelectromechanical component or assembly. The sensor structure can be assigned to a microchip. The sensor structure can be an integrated system.

The sensor structure can be deflected depending on the environmental variable due to the design, dimensions, fastening, storage, mounting and/or material of the sensor structure. The deflection of the sensor membrane can be a bending.

The converter unit is a component or assembly that converts the deflection directly or indirectly into an analog or digital, measurable and/or interpretable measured variable. The converter unit can provide the measured variable proportional or inversely proportional to changes in the deflection.

The measured variable can be an electrical measured variable that is measurable and/or interpretable. The measured variable can be an electrical voltage, an electrical current or an electrical resistance.

The deposit can be a liquid or solid accumulation. The material of the deposit differs from the material or substance of the ambient medium. The deposit can consist of a single substance or a plurality of substances. The deposit can be water, dirt, dust or the like. The deposit may have adverse effects on the measurement of the environmental variable by the environmental sensor. The measurement of the environmental variable may be impaired by the deposit, in particular unreliable.

Detecting the deposit can include recognizing the deposit, in particular whether a deposit is present on the sensor structure or not and/or detecting at least one property of the deposit, in particular a weight, a density, a dimension, a material type or similar.

According to an example embodiment of the present invention, the measured variable can be changed by the deposit compared to the state without the deposit. Detecting the deposit can include detecting the measured variable. The measured variable can depend on a position on the sensor structure, a dimension, a mass, a density, an electrical property and/or a dielectric property of the deposit.

The mechanical excitation can be measured by a microphone and/or acceleration sensor. The measurement can be used as a reference measurement to verify and/or calibrate the excitation.

An external excitation is understood to be an excitation that arises outside the environmental sensor and is transmitted thereto or allowed to act thereon. The generation of excitation within the environmental sensor may be absent or at most secondary, in particular subordinate.

In a preferred example embodiment of the present invention, it is provided that the deposit is present on a partial region of the sensor structure and a position, dimension and/or distribution of the deposit on the sensor structure can change due to the excitation movement. The measured variable can be dependent on the position, dimension and/or distribution of the deposit on the sensor structure.

In a special example embodiment of the present invention, it is advantageous if the measured variable can change depending on the excitation movement and the detection of the deposit includes an evaluation of the change in the measured variable. The environmental variable can remain constant while the change in the measured variable is being detected. The change in the measured variable can be a change in the amplitude, phase, frequency and/or polarity of the measured variable.

In a preferred example embodiment of the present invention, it is advantageous if, during the excitation movement, a maximum value of the measured variable and a minimum value of the measured variable are detected and the detection of the deposit is dependent on a value difference between the maximum value and the minimum value. The detection of the deposit can be dependent on a ratio of the amount of the value difference to an amount of a predetermined preset difference. If the value difference exceeds or reaches the preset difference, it can be concluded that deposits are present. If the value difference is less than the preset difference, it can be concluded that there is no deposit on the sensor structure.

The preset difference may have been detected in advance when the occurrence of deposits on the sensor structure is excluded. When the preset difference is detected, the same excitation, in particular with the same amplitudes and frequencies, can be used as when the method for sensor state detection is carried out.

In an advantageous example embodiment of the present invention, it is provided that a dynamic value of the measured variable is detected during the excitation movement and the detection of the deposit is dependent on a comparison of the dynamic value with a dynamic reference value. The dynamic value can be a time gradient of the measured variable. The dynamic value can be a variance of the measured variable. The dynamic reference value may have been detected when the occurrence of deposits on the sensor structure was excluded. When the dynamic reference value is detected, the same excitation, in particular with the same amplitudes and frequencies, can be used as when the method for sensor state detection is carried out. The dynamic reference value can be detected after the environmental sensor is completed, before the environmental sensor is first put into operation, or by repeated measurements during operation of the environmental sensor. The dynamic reference value can be stored in an accessible manner.

The comparison between the dynamic value and dynamic reference value can be the formation of a dynamic value difference between the dynamic value and dynamic reference value. The detection of the deposit can be dependent on the dynamic value difference, in particular on an amount of the dynamic value difference. If the dynamic value difference exceeds or reaches a preset dynamic difference, in particular an amount of the preset dynamic difference, it can be concluded that a deposit is present. If the dynamic value difference falls below the preset dynamic difference, it can be concluded that there is no deposit on the sensor structure. The preset dynamic difference may have been detected in advance and stored under the same excitation but without deposition.

In a special embodiment of the present invention, it is advantageous if the environmental sensor is a capacitive environmental sensor and the converter unit provides the measured variable as an electrical measured variable depending on an electrical capacitance influenced at least by the deflection. The capacitive environmental sensor can be a capacitive pressure sensor. The electrical capacitance can also be influenced by the deposit in addition to the deflection. The influence of the deposit on the electrical capacitance can occur indirectly through a deflection caused by the deposit and/or directly through a change in the electrical permittivity with the deposit. The converter unit can provide the measured variable depending on the indirect and direct influence on the electrical capacitance.

In a special example embodiment of the present invention, it is advantageous if the electrical capacitance can change depending on the excitation movement. A change in the measured variable may be dependent on the change in the excitation movement.

A preferred example embodiment of the present invention is advantageous in which the mechanical excitation is a dynamic excitation in the form of a vibration and/or an acoustic oscillation. The dynamic excitation can have a time-varying amplitude and/or frequency of excitation. The amplitude and/or frequency may vary periodically over time. The amplitude and/or frequency can be swept through in a progressively increasing or decreasing manner over time (amplitude sweep, frequency sweep). The sweep can be performed once or repeatedly. The acoustic oscillation can be an airborne sound oscillation.

According to an example embodiment of the present invention, an environmental sensor system is provided. The detection system can have an evaluation unit for recording the measured variable. The evaluation unit can be arranged inside or outside the environmental sensor.

According to the present invention, a mobile consumer device is porovided. This allows the mobile consumer device to operate more reliably. The mobile consumer device can be a wearable, in particular a smartwatch, a fitness tracker, an AR device and/or a VR device. The mobile consumer device can be a smartphone, a tablet or a portable computer.

The excitation apparatus can be assigned to a functional unit already present in the mobile consumer device. This allows the mobile consumer device to be designed more cost-effectively. The excitation apparatus can be formed by the functional unit. The excitation apparatus can be a loudspeaker for generating acoustic oscillations as mechanical excitation. The excitation apparatus can be a vibration generator for generating vibrations as mechanical excitation.

According to an example embodiment of the present invention, the excitation apparatus can perform the mechanical excitation for detecting the deposit as a subordinate function that is secondary to a main function. The main function of the loudspeaker can be entertainment and/or communication with and/or signaling to the user operating the mobile consumer device. The main function of the vibration generator can be to signal the user. The excitation apparatus can trigger the mechanical excitation as a side effect when the main function is performed (for example, a ring function). The acoustic oscillation can be formed by the acoustic oscillations emanating from the loudspeaker during communication with or signaling to the user. The vibration can be caused by the vibrations that occur when signaling to the user.

According to the present invention, the method for sensor state detection can be carried out during operation of the mobile consumer device. The method for sensor state monitoring can be carried out (exclusively) during or outside of a main operation (as a user-interactive operation) of the mobile consumer device. The method for sensor state detection can be carried out during operation of the excitation apparatus. The excitation apparatus can be operated (exclusively) during or outside of a main operation (as a user-interactive operation) of the mobile consumer device.

The present invention further relates to a computer program product, during the execution of which on a computer at least the detection of the deposit takes place in the method for sensor state detection having at least one of the above-described features.

Further advantages and advantageous embodiments of the present invention can be found in the description of the figures and in the figures.

### BRIEF DESCRIPTION OF THE DESCRIPTION

The present invention is described in detail below with reference to the figures.

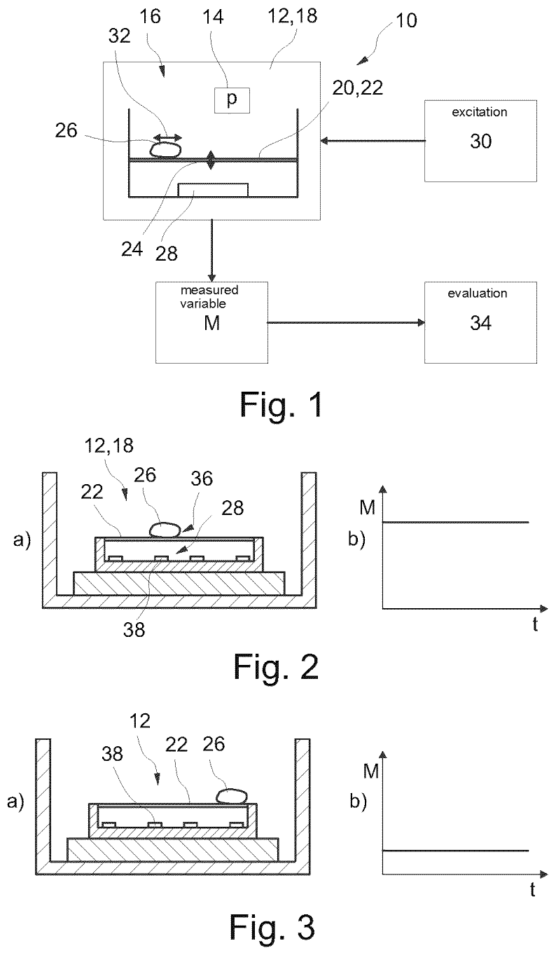

FIG. 1 shows a method for sensor state detection in an example embodiment of the present invention.

FIG. 2 shows an environmental sensor of an example embodiment of the present invention in a first state.

FIG. 3 shows the environmental sensor of FIG. 2 in a second state.

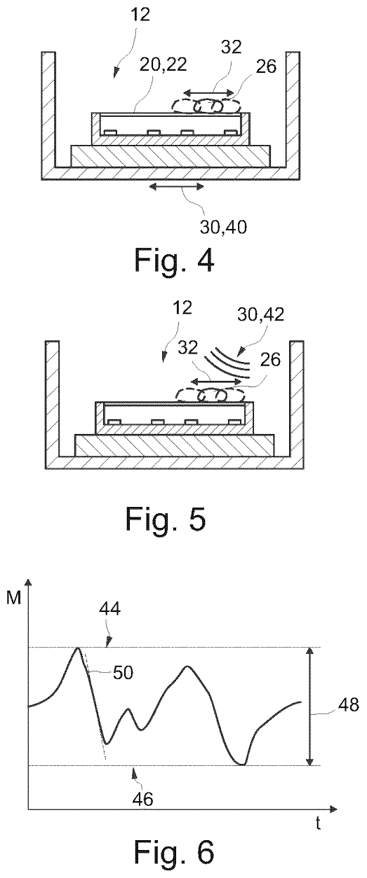

FIG. 4 shows an environmental sensor when a method is carried out for sensor state detection in an example embodiment of the present invention.

FIG. 5 shows an environmental sensor when a method is carried out for sensor state detection in a further example embodiment of the present invention.

FIG. 6 shows a measured variable diagram when a method is carried out for sensor state detection in a further example embodiment of the present invention.

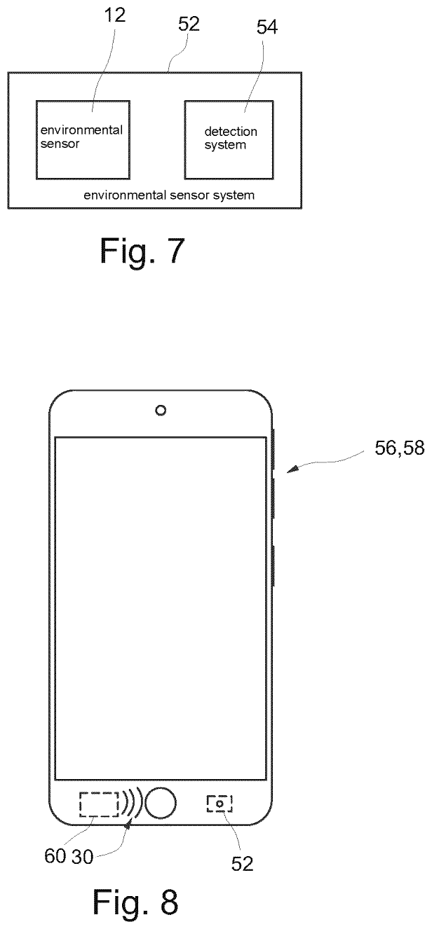

FIG. 7 shows an environmental sensor system in an example embodiment of the present invention.

FIG. 8 shows a mobile consumer device in an example embodiment of the present invention.

### DETAILED DESCRIPTION OF EXAMPLE EMBODIMENT

FIG. 1 shows a method for sensor state detection in a special embodiment of the present invention. The method for sensor state detection 10 is carried out to detect a sensor state of an environmental sensor 12. The environmental sensor 12 is provided to measure a physical environmental variable 14 of an ambient medium 16. The environmental sensor 12 is designed in particular as a micromechanical pressure sensor 18 that detects the environmental variable 14 as a capacitive pressure sensor 18. The environmental sensor 12 comprises a micromechanical sensor structure 20, in this case a sensor membrane 22, which undergoes a deflection 24 depending on the environmental variable 14. An ambient pressure p of the ambient medium 16, in this case in particular air, as a physical environmental variable 14 exerts a force on the surface of the sensor structure 20, which deflects the sensor membrane 22, in this case in particular bends it.

The ambient medium 16 acts directly on the sensor structure 20, which is thus exposed to contamination. Therefore, at least one interfering deposit 26 entering via the ambient medium 16 can be deposited on the sensor structure 20, which deposit can impair the measurement of the environmental variable 14.

The environmental sensor 12 comprises a converter unit 28 for providing a measured variable M depending on the deflection 24 of the sensor membrane 22. The converter unit 28 can provide the measured variable M as an electrical measured variable depending on an electrical capacitance influenced by the deflection 24.

The deposit 26 present on the sensor structure 20 is detected by means of an excitation 30 deviating from the physical environmental variable 14. The excitation 30 is a mechanical excitation acting externally on the environmental sensor 12, by means of which the deposit 26 moves with an excitation movement 32 on the sensor structure 20.

The measured variable M can change depending on the excitation movement 32, and the detection of the deposit 26 can include an evaluation 34 of the change in the measured variable M.

FIG. 2 shows an environmental sensor of a special embodiment of the present invention in a first state. The environmental sensor 12 is designed as a capacitive pressure sensor 18 and, as shown in FIG. 2 a), has the deposit 26 on a partial region 36 of the sensor membrane 22, which deposit does not move on the sensor membrane 22. FIG. 2 b) shows the time course of the electrical measured variable M. The measured variable M is on the one hand dependent on the physical environmental variable and on the other hand on the deposit 26. Because the deposit 26 is located directly above a measuring element 38 of the converter unit 28, the influence of the deposit 26 on the measured variable M is large due to the changed electrical permittivity.

FIG. 3 shows the environmental sensor of FIG. 2 in a second state. FIG. 3 a) shows the environmental sensor 12 of FIG. 2 a), wherein, by contrast, the deposit 26 is located at a position on the sensor membrane 22 that is offset from the position in FIG. 2 a). The environmental variable, however, is the same as the one in the state shown in FIG. 2 a). FIG. 3 b) shows the time course of the electrical measured variable M. The magnitude of the measured variable M is smaller than in FIG. 2 b), because the deposit 26 is further away from the measuring element 38 than in FIG. 2 a).

FIG. 4 shows an environmental sensor when a method is carried out for sensor state detection in a special embodiment of the present invention. The environmental sensor 12 is similar to that of FIG. 2, with a deposit 26 located on the sensor membrane 22. A position of the deposit 26 on the sensor structure 20 can change due to the excitation movement 32, shown here by the dashed lines. The excitation movement 32 is caused by the mechanical excitation 30, which is a dynamic excitation in the form of a vibration 40.

FIG. 5 shows an environmental sensor when a method is carried out for sensor state detection in a further special embodiment of the present invention. The environmental sensor 12 is similar to that of FIG. 4, wherein the mechanical excitation 30 is a dynamic excitation in the form of an acoustic oscillation 42, which causes the excitation movement 32 of the deposit 26. The acoustic oscillation 42 is preferably an airborne sound oscillation.

FIG. 6 shows a measured variable diagram when a method is carried out for sensor state detection in a further special embodiment of the present invention. The time profile of the measured variable M is subject to changes due to the excitation movement. During the excitation movement, a maximum value 44 of the measured variable M and a minimum value 46 of the measured variable M can be detected and the deposit can be detected depending on a value difference 48 between the maximum value 44 and the minimum value 46.

Additionally or alternatively, a dynamic value 50 of the measured variable M, for example a time gradient of the measured variable M, can be detected during the excitation movement and the deposit can be detected depending on a comparison of the dynamic value 50 with a dynamic reference value.

FIG. 7 shows an environmental sensor system in a special embodiment of the present invention. The environmental sensor system 52 comprises an environmental sensor 12, for example as shown in FIG. 2, for measuring at least one physical environmental variable and a detection system 54 for carrying out the method for sensor state detection, for example as shown in FIG. 1.

FIG. 8 shows a mobile consumer device in a special embodiment of the present invention. The mobile consumer device 56 is designed as a smartphone 58 and comprises an environmental sensor system 52, for example as shown in FIG. 7, and an excitation apparatus 60 for generating the mechanical excitation 30 when the method for sensor state detection shown, for example, in FIG. 1, is carried out.

1-10. (canceled)

11. A method for sensor state detection of an environmental sensor for measuring at least one physical environmental variable of an ambient medium, comprising the following steps:
providing the environmental sensor including a micromechanical sensor structure that can be deflected depending on the environmental variable, is exposed to the ambient medium and on which at least one interfering deposit entering via the ambient medium can be deposited and further including a converter unit configured to provide a measured variable depending on the deflection of the sensor structure; and
detecting an existing deposit of an interfering deposit type on the sensor structure via an excitation deviating from the environmental variable;
wherein the excitation is a mechanical excitation acting externally on the environmental sensor, by which the deposit moves with an excitation movement on the sensor structure.

12. The method for sensor state detection according to claim 11, wherein the deposit is present on a partial region of the sensor structure and a position of the deposit and/or dimension of the deposit and/or distribution of the deposit on the sensor structure can change due to the excitation movement.

13. The method for sensor state detection according to claim 11, wherein the measured variable can change depending on the excitation movement and the detection of the deposit includes an evaluation of the change in the measured variable.

14. The method for sensor state detection according to claim 13, wherein during the excitation movement, a maximum value of the measured variable and a minimum value of the measured variable are detected and the detection of the deposit is dependent on a value difference between the maximum value and the minimum value.

15. The method for sensor state detection according to claim 13, wherein a dynamic value of the measured variable is detected during the excitation movement and the detection of the deposit is dependent on a comparison of the dynamic value with a dynamic reference value.

16. The method for sensor state detection according to claim 13, wherein the environmental sensor is a capacitive environmental sensor and the converter unit provides the measured variable as an electrical measured variable depending on an electrical capacitance influenced at least by the deflection.

17. The method for sensor state detection according to claim 16, wherein the electrical capacitance can change depending on the excitation movement.

18. The method for sensor state detection according to claim 11, wherein the mechanical excitation is a dynamic excitation in the form of a vibration and/or an acoustic oscillation.

19. An environmental sensor system, comprising:
an environmental sensor configured to measure at least one physical environmental variable and including a micromechanical sensor structure that can be deflected depending on the environmental variable, is exposed to the ambient medium and on which at least one interfering deposit entering via the ambient medium can be deposited and further including a converter unit configured to provide a measured variable depending on the deflection of the sensor structure; and
a detection system configured to carry out a sensor state detection of the environmental sensor, the detection system configured to:
detect an existing deposit of an interfering deposit type on the sensor structure via an excitation deviating from the environmental variable;
wherein the excitation is a mechanical excitation acting externally on the environmental sensor, by which the deposit moves with an excitation movement on the sensor structure.

20. A mobile consumer device, comprising:
an environmental sensor system including:
an environmental sensor configured to measure at least one physical environmental variable and including a micromechanical sensor structure that can be deflected depending on the environmental variable, is exposed to the ambient medium and on which at least one interfering deposit entering via the ambient medium can be deposited and further including a converter unit configured to provide a measured variable depending on the deflection of the sensor structure, and
a detection system configured to carry out a sensor state detection of the environmental sensor, the detection system configured to:
detect an existing deposit of an interfering deposit type on the sensor structure via an excitation deviating from the environmental variable;
wherein the excitation is a mechanical excitation acting externally on the environmental sensor, by which the deposit moves with an excitation movement on the sensor structure; and
an excitation apparatus configured generate the mechanical excitation when the detection system carries out the sensor state detection.
